(19) United States
(12) Patent Application Publication
(10) Pub. No.: US 2007/0212833 A1
(43) Pub. Date: Sep. 13, 2007

(54) Methods for making a nonvolatile memory device comprising a shunt silicon layer

(75) Inventors: Chi-Pin Lu, Hsinchu (TW); Ling-Wuu Yang, Hsinchu (TW); Kuang-Chao Chen, Hsinchu (TW)

Correspondence Address: BAKER & MCKENZIE LLP;PATENT DEPARTMENT, 2001 ROSS AVENUE, SUITE 2300, DALLAS, TX, 75201, US

(73) Assignee: Macronix International Co., Ltd.

(21) Appl. No.: 11/374,337

(22) Filed: Mar. 13, 2006

(51) Int. Cl. H01L 21/336

(52) U.S. Cl. 438/257

(57) ABSTRACT

A nitride read only memory comprises a selectively grown, epitaxial, shunt silicon layer (shunt layer) that reduces the bit line sheet resistance and increases bit line mobility. The shunt layer can be grown by a in situ, P-doped deposit at high temperature. A bit line interface without native oxide and excellent electron mobility can be achieved using the methods for selective epitaxial growth described herein.

### BACKGROUND

1. Field of the Invention

The embodiments described herein related generally to non-volatile read only memory, and more particularly to methods to reduce the bit line sheet resistance in a nitride read only memory.

2. Background of the Invention

Nitride read only memories represent an advance in non-volatile memory design that allow for increased density, reduced memory size, and reduced manufactured costs. Significantly, nitride read only memories allow multi-bit storage in a single cell, without resort to multi-level cell (MLC) techniques, which can be difficult to achieve and control due to the strict control of threshold voltages that MLC technology requires.

FIG. 1 is a diagram illustrating a conventional nitride read-only memory structure 100. As can be seen, nitride read-only memory 100 is constructed on a silicon substrate 102. The silicon substrate can be a P-type silicon substrate or an N-type silicon substrate; however, for various design reasons P-type silicon substrates are often preferred. Drain/source regions 104 and 106 can then be implanted in substrate 102. A trapping structure 108 is then configured on substrate 102 between source/drain regions 104 and 106. Control gate 110 is then formed on top of trapping layer 108.

Drain/source regions 104 and 106 are silicon regions that are doped to be the opposite type as that as substrate 102. For example, where a P-type silicon substrate 102 is used, N-type drain/source regions 104 and 106 can be implanted therein.

Charge trapping structure 108 comprises a nitride trapping layer as well as an isolating oxide layer between the trapping layer and the channel in substrate 102. In other embodiments, trapping structure 108 can comprise a nitride trapping layer sandwiched between two isolating, or dielectric layers, such as oxide layers. Such a configuration is often referred to as an Oxide-Nitride-Oxide (ONO) trapping layer.

Charge can be accumulated and confined within trapping structure 108 next to drain/source regions 104 and 106, effectively storing two separate and independent charges. Each charge can be maintained in one of two states, either programmed or erased, represented by the presence or absence of a pocket of trapped electrons. This enables the storage of two bits of information without the complexities associated with multilevel cell technology.

Each storage area in nitride read-only memory cell 100 can be programmed independently of the other storage area. A nitride read-only memory cell is programmed by applying a voltage that causes negatively charged electrons to be injected into the nitride layer of trapping structure 108 near one end of the cell. Erasing is accomplished by applying voltages that cause holes to be injected into the nitride layer where they can compensate for electrons previously stored in the nitride layer during programming.

A nitride read only memory device is constructed by manufacturing arrays of memory cells such as that cell illustrated in FIG. 1. Arrays are constructed by tying the cells together via word and bit lines. The bit lines are often polysilicon lines, while the word lines can be polysilicon or metal. High electron mobility, and low resistance in the word and bit lines are important characteristics if the high performance demanded by current applications is to be met. If the word and/or bit lines exhibit high resistance, or low mobility, then the access times for the device array will be limited. Further, higher voltages will be required to drive the word or bit lines, which increases power consumption, which can have a negative impact especially in mobile applications for which power consumption is a key design parameter.

Unfortunately, when manufacturing sub-micron, conventional nitride read only memory, large bit line resistance can be an issue. To overcome this issue, heavy bit line implant procedures, and high temperature thermal treatments are required. The heavy implant procedures prolongs the manufacturing process and can create a bottleneck that reduces manufacturing throughput. The high temperature procedures can tax, and even exceed the thermal budget for the manufacturing process.

Accordingly, conventional nitride read only memory devices require a tradeoff between performance on the one hand, and throughput, which equates to cost, on the other.

### SUMMARY

A nitride read only memory comprises a selectively grown, epitaxial, shunt silicon layer (shunt layer) that reduces the bit line sheet resistance and increases bit line mobility. The shunt layer can be grown by a in situ, P-doped deposit at high temperature.

In one aspect, a bit line interface without native oxide and excellent electron mobility can be achieved using the methods for selective epitaxial growth described herein.

These and other features, aspects, and embodiments of the invention are described below in the section entitled “Detailed Description.”

### BRIEF DESCRIPTION OF THE DRAWINGS

Features, aspects, and embodiments of the inventions are described in conjunction with the attached drawings, in which:

FIG. 1 is a diagram illustrating a conventional nitride read only memory;

FIG. 2 is a diagram illustrating certain steps in an example method for manufacturing a nitride read only memory in accordance with one embodiment;

FIG. 3 is a diagram illustrating further steps in an example method for manufacturing a nitride read only memory in accordance with one embodiment;

FIG. 4 is a diagram illustrating further steps in an example method for manufacturing a nitride read only memory in accordance with one embodiment;

FIG. 5 is a diagram illustrating further steps in an example method for manufacturing a nitride read only memory in accordance with one embodiment; and

FIG. 6 is a SEM image of a nitride read only memory made in accordance with the method illustrated in FIGS. 2-5.

### DETAILED DESCRIPTION

While the examples described herein relate to nitride read only memories, the methods described are not necessarily limited to nitride read only memories. Accordingly, it will be understood that the methods described herein can also be used in the manufacture and fabrication of other non-volatile memory devices. It will also be understood that any dimensions, measurements, ranges, test results, numerical data, etc., are approximate in nature and unless otherwise stated not intended as precise data. The nature of the approximation involved will depend on the nature of the data, the context and the specific embodiments or implementations being discussed.

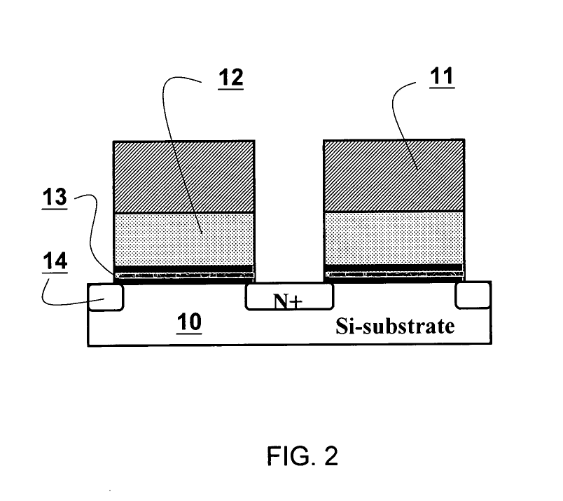

FIG. 2 is a diagram illustrating certain process steps for manufacturing a nitride read only memory device in accordance with one embodiment. The process starts with a silicon substrate 10. It will be understood that substrate 10 can be a P-type substrate or a N-type substrate. It will also be understood that P-type substrates are often preferred for various reasons. In the example of FIG. 2-5, substrate 10 is a P-type substrate; however, this should not be seen as limiting the methods and apparatus described herein to P-type substrates. In other embodiments, N-type substrates can be used and the methods described herein still applied, with the necessary adjustments in the doping type of various layers and regions. In certain instances, these differences will be called out in the descriptions that follow.

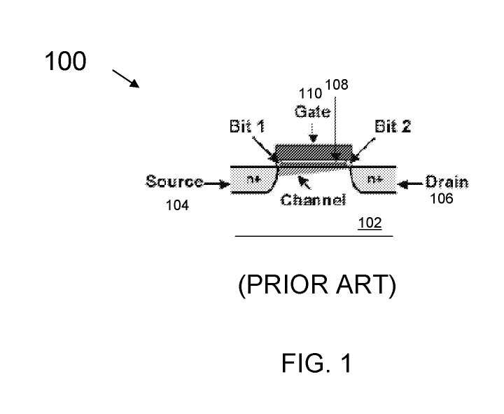

A trapping structure 13 is formed on substrate 10. In the example of FIG. 1, trapping structure 13 comprises three layers, a nitride layer, such as a silicon nitride (SiN) layer, sandwiched between two dielectric layers, such as silicon dioxide (SiO₂) layers. Such a structure is commonly referred as a Oxide-Nitride-Oxide (ONO) structure. In other embodiments, e.g., for other types of non-volatile memory devices, trapping structure 13 can comprise a ON structure or simply a Nitride trapping layer. ONO structures are constructed by growing an oxide layer on substrate 10 in a thermal process, often carried out in a furnace. The nitride layer is then deposited using an appropriate deposition process such as chemical vapor deposition (CVD). The second oxide layer is then formed over the nitride layer. The lower oxide layer is often referred to as a tunnel oxide layer, and the nitride layer is often referred to as the trapping layer.

A polysilicon layer 12 is then formed over the trapping structure. A SiN layer 11 can then be formed over polysilicon layer 12. SiN layer 11 can act as a stop layer for etching or polishing processes carried out later in the manufacture of the nitride read only device. A photoresist layer (not shown) can then formed over SiN layer 11. The photoresist can define a pattern for polysilicon layer 12. After the photoresist is formed, SiN layer 11, polysilicon layer 12 and trapping structure 13 can be etched according to the patterned defined by the photoresist as illustrated in FIG. 2.

Source/drain regions 14 can then be formed in the upper layer of substrate 10 by implanting the appropriate dopants. In this case, regions 14 are doped to be N+-regions, since substrate 10 is a P-type substrate. In embodiments where substrate 10 is a N-type substrate, then regions 14 are doped to be P+-type regions.

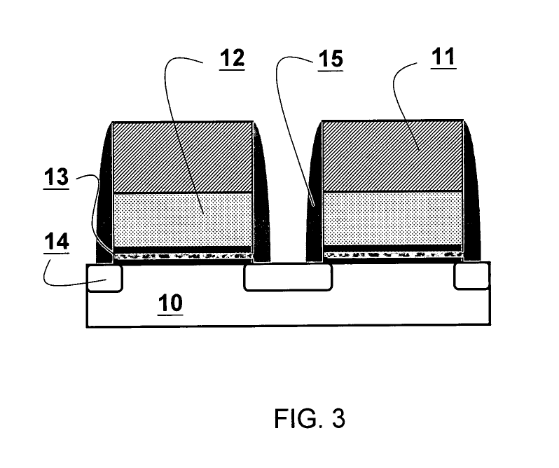

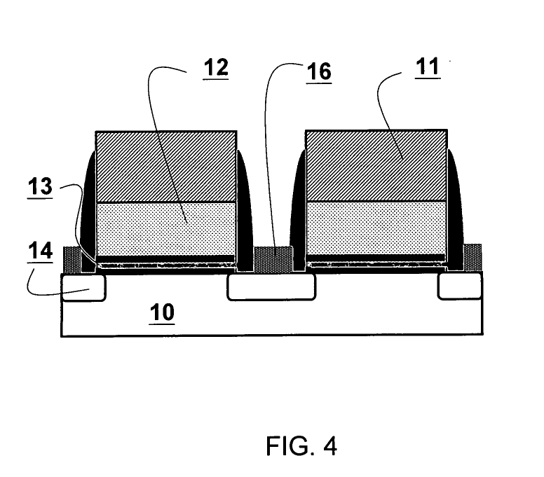

As illustrated in FIG. 3, an oxide layer (not shown) can then be deposited over substrate 10 so as to fill in the areas between polysilicon areas 12. For example, the oxide layer can be formed by a Low Pressure Tetra-Ethyl-Ortho-Silicate (LP-TEOS) deposition process. The TEOS oxide layer can then be anisotropically etched to form side walls 15. As illustrated in FIG. 4, shunt layer 16 can then be formed over the buried diffusion areas between polysilicon regions 12. In one embodiment, the wafer can be cleaned, e.g., using a batch DHF process with a selectivity of 200:1. Shunt layer 16 can then be grown using a selective epitaxial process.

For example, in one embodiment, shunt layer 16 is grown using a selective epitaxial process with 9*E19 atoms/cm2 in-situ P doped concentration deposited at about 700 C in the buried diffusion region. The deposition pressure can, e.g., be controlled under about 300 Torr, and DCS (SiH₂Cl₂) can be injected with HCl to enable the selectively epitaxial growth at about 700 C. At the same time, a PH₃ gas can be injected to form the in-situ doped exptaxial silicon layer.

In certain embodiments, during the selective epitaxial process described above, an in-situ high temperature H₂ treatment, e.g., at a temperature in the range of about 900 C-1000 C, can be applied to remove any native oxide remaining in the buried diffusion region. It will be understood that the parameters provided above are by way of example only and that the actual parameters used will depend on the requirements of a specific embodiment.

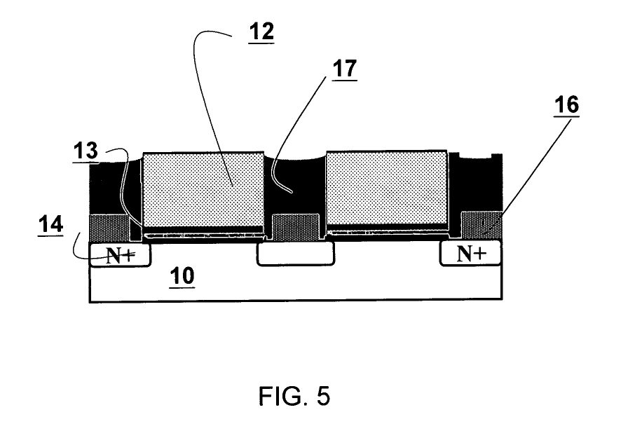

As illustrated in FIG. 5, a dielectric layer 17 can then be formed over shunt layer 16. The dielectric layer 17, such as silicon oxide, is formed by high density plasma chemical vapor deposition (HDP CVD). A portion of the dielectric layer 17 is removed to expose a part of the SiN layer 11 by wet etching. SiN layer 11 and excess dielectric layer 17 can then be removed, e.g., via an etching process that uses polysilicon layer 12 as an etch stop. The SiN layer 11 is removed, for example, by using hot phosphoric acid. Shunt layer 16 can, e.g., have a thickness in the range of about 200-400 angstroms. Although it will be understood that in other embodiments, different thicknesses can be achieved as required.

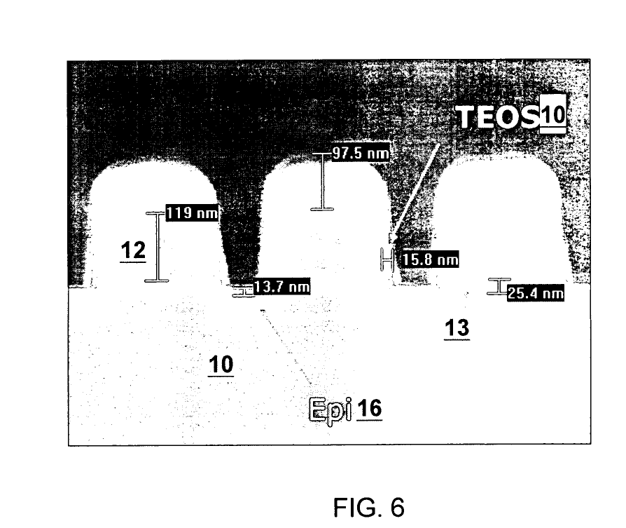

FIG. 6 is a Scanning Electron Microscope (SEM) image showing an example nitride read only memory formed using the process described in relation to FIGS. 2-5. FIG. 6 illustrates example dimensions that can be achieved for the various layers and regions comprising the nitride read only memory. It will be understood, however, that these dimensions are both approximate and by way of example only. Thus, other dimensions can be achieved depending on the requirements of a specific embodiment.

In the example of FIG. 6, shunt layer 16 has a thickness of about 13.7 nm, while trapping structure 13 has a thickness of about 25.4 nm. Sidewalls 15 have a thickness of about 15.8 nm and polysilicon layer 12 has a thickness of about 119 nm. As illustrated, another polysilicon layer can be formed over polysilicon layer 12 and can have a thickness of about 97.5 nm.

While certain embodiments of the inventions have been described above, it will be understood that the embodiments described are by way of example only. Accordingly, the inventions should not be limited based on the described embodiments. Rather, the scope of the inventions described herein should only be limited in light of the claims that follow when taken in conjunction with the above description and accompanying drawings.

1. A method for making a nonvolatile memory device on a wafer, comprising:
forming a gate structure on a substrate;
forming diffusion regions adjacent to the gate structure; and
forming an epitaxial silicon shunt layer in the diffusion region using a selective epitaxial growth process.

2. The method of claim 1, wherein forming the gate structure comprises:
forming a trapping structure over the substrate;
forming a polysilicon layer over the trapping structure;
forming a nitride layer over the polysilicon layer; and
etching the nitride layer, polysilicon layer and trapping layer.

3. The method of claim 1, further comprising depositing an oxide layer over the diffusion region and anisotropically etching the oxide layer to form sidewalls along the sides of the gate structure, wherein the shunt layer is formed within the sidewalls.

4. The method of claim 1, further comprising forming a dielectric layer over the shunt layer.

5. The method of claim 1, further comprising cleaning the wafer before forming the shunt layer.

6. The method of claim 5, wherein cleaning the wafer comprises using a batch DHF process with a selectivity of 200:1.

7. (canceled)

8. The method of claim 1, wherein forming the epitaxial silicon layer comprises growing the epitaxial silicon layer using a selective epitaxial process.

9. The method of claim 8, wherein the selective epitaxial process comprises growing the epitaxial silicon layer using a selective epitaxial process with 9*E19 atoms/cm2 in-situ P doped concentration deposited at about 700 C.

10. The method of claim 9, wherein the deposition pressure is controlled under about 300 Torr.

11. The method of claim 10, wherein DCS (SiH₂Cl₂) can be injected with HCl to enable the selectively epitaxial silicon growth.

12. The method of claim 11, wherein a PH₃ gas is injected to form the in-situ doped epitaxial silicon layer.

13. The method of claim 8, further comprising removing native oxide using an in-situ high temperature H₂ treatment.

14. The method of claim 13, wherein the in-situ high temperature H₂ treatment is performed with a temperature in the range of about 900 C-1000 C.

15. A method for making a nonvolatile memory device on a wafer, comprising:
forming a gate structure on a substrate;
forming diffusion regions adjacent to the gate structure;
removing any native oxide using a thermal treatment; and
forming an epitaxial silicon shunt layer in the diffusion region using a selective epitaxial growth process.

16. The method of claim 15, wherein forming the gate structure comprises:
forming a trapping structure over the substrate;
forming a polysilicon layer over the trapping structure;
forming a nitride layer over the polysilicon layer; and
etching the nitride layer, polysilicon layer and trapping layer.

17. The method of claim 15, further comprising depositing an oxide layer over the diffusion region and anistropically etching the oxide layer to form sidewalls along the sides of the gate structure, wherein the shunt layer is formed within the sidewalls.

18. The method of claim 15, further comprising forming a dielectric layer over the shunt layer.

19. The method of claim 15, further comprising cleaning the wafer before forming the shunt layer.

20. The method of claim 19, wherein cleaning the wafer comprises using a batch DHF process with a selectivity of 200:1.

21. The method of claim 15, wherein the selective epitaxial growth process comprises growing the epitaxial silicon shunt layer using a selective epitaxial process with 9*E19 atoms/cm2 in-situ P doped concentration deposited at about 700 C.

22. The method of claim 15, wherein DCS (SiH₂Cl₂) can be injected with HCl to enable the selectively epitaxial silicon growth.

23. The method of claim 15, wherein a PH₃ gas is injected to form the in-situ doped epitaxial silicon shunt layer.

24. The method of claim 15, further comprising removing native oxide using an in-situ high temperature H₂ treatment.

25. The method of claim 24, wherein the in-situ high temperature H₂ treatment is performed with a temperature in the range of about 900 C-1000 C.

26. A non-volatile memory device, comprising:
a substrate;
a gate structure, comprising a trapping layer and a polysilicon layer, formed on the substrate;
a diffusion region formed in the substrate adjacent to the gate structure; and
an epitaxial silicon shunt layer formed in the diffusion region.

27. The non-volatile memory device of claim 26, wherein the epitaxial silicon shunt layer comprises a thickness in the range of about 200-400 angstroms.

28. The non-volatile memory device of claim 26, wherein the epitaxial silicon shunt layer has a thickness of about 13.7 nm.

29. The non-volatile memory device of claim 26, wherein the trapping structure has a thickness of about 25.4 nm.

30. The non-volatile memory device of claim 26, further comprising oxide side walls along the sides of the gate structure.

31. The non-volatile memory device of claim 30, wherein the oxide side walls have a thickness of about 15.8 nm.

32. The non-volatile memory device of claim 26, wherein the polysilicon layer has a thickness of about 119 nm.

33. The non-volatile memory device of claim 26, wherein the trapping structure is an ONO trapping structure.
